(19) United States
(12) Patent Application Publication
(10) Pub. No.: US 2026/0313802 A1
(43) Pub. Date: Oct. 8, 2026

(54) WIRING SUBSTRATE AND METHOD FOR MANUFACTURING WIRING SUBSTRATE

(71) Applicant: IBIDEN CO., LTD., Gifu (JP)

(72) Inventor: Katsuyuki SANO, Gifu (JP)

(73) Assignee: IBIDEN CO., LTD., Gifu (JP)

(21) Appl. No.: 19/293,384

(22) Filed: Aug. 7, 2025

(30) Foreign Application Priority Data
Aug. 9, 2024 (JP) 2024-134447

(51) Int. Cl. H05K 1/14; H05K 1/11; H05K 3/36; H05K 3/40; H05K 3/46

(52) U.S. Cl. CPC H05K 1/142; H05K 1/113; H05K 1/144; H05K 3/368; H05K 3/4007; H05K 3/4626; H05K 2201/041; H05K 2201/09481

(57) ABSTRACT

A wiring substrate includes first substrates each including a first core substrate, first conductor layers and first insulating layers, one or more second substrates each including a second core substrate, second conductor layers and second insulating layers, and conductor bumps connecting a surface of each first substrate to a second surface of the second substrate or substrates on the opposite side with respect to a first surface of the second substrate or substrates such that the first surface of the second substrate or substrates have a component mounting region. The first substrates have substantially the same thickness. The first conductor layers and the first insulating layers are laminated on first and second surfaces of the first core substrate. The second conductor layers and the second insulating layers are laminated on first and second surfaces of the second core substrate.

### CROSS-REFERENCE TO RELATED APPLICATIONS

The present application is based upon and claims the benefit of priority to Japanese Patent Application No. 2024-134447, filed Aug. 9, 2024, the entire contents of which are incorporated herein by reference.

### BACKGROUND OF THE INVENTION

### Field of the Invention

The present invention relates to a wiring substrate and a method for manufacturing the wiring substrate.

### Description of Background Art

Japanese Patent Application Laid-Open Publication No. 2012-160701 describes a semiconductor mounting member. The entire contents of this publication are incorporated herein by reference.

### SUMMARY OF THE INVENTION

According to one aspect of the present invention, a wiring substrate includes first substrates each including a first core substrate, first conductor layers and first insulating layers, one or more second substrates each including a second core substrate, second conductor layers and second insulating layers, and conductor bumps connecting a surface of each of the first substrates to a second surface of the second substrate or substrates on the opposite side with respect to a first surface of the second substrate or substrates such that the first surface of the second substrate or substrates have a component mounting region. The first substrates have substantially the same thickness and are formed such that the first conductor layers and the first insulating layers are laminated on a first surface of the first core substrate and on a second surface of the first core substrate on the opposite side with respect to the first surface of the first core substrate, and the second substrate or substrates are formed such that the second conductor layers and the second insulating layers are laminated on a first surface of the second core substrate and on a second surface of the second core substrate on the opposite side with respect to the first surface of the second core substrate.

According to another aspect of the present invention, a method for manufacturing a wiring substrate includes preparing first substrates each including a first core substrate, first conductor layers and first insulating layers, preparing one or more second substrates each including a second core substrate, second conductor layers and second insulating layers, and connecting a surface of each of the first substrates to a second surface of the second substrate or substrates on the opposite side with respect to a first surface of the second substrate or substrates via conductor bumps such that the first surface of the second substrate or substrates have a component mounting region. The first substrates have substantially the same thickness and are formed such that the first conductor layers and the first insulating layers are laminated on a first surface of the first core substrate and on a second surface of the first core substrate on the opposite side with respect to the first surface of the first core substrate, and the second substrate or substrates are formed such that the second conductor layers and the second insulating layers are laminated on a first surface of the second core substrate and on a second surface of the second core substrate on the opposite side with respect to the first surface of the second core substrate.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2 is a top view of the wiring substrate illustrated in FIG. 1;

FIG. 3 is a top view illustrating another example of a wiring substrate according to an embodiment of the present invention;

FIG. 4 is a top view illustrating yet another example of a wiring substrate according to an embodiment of the present invention;

FIG. 5 is a top view illustrating still another example of a wiring substrate according to an embodiment of the present invention;

FIG. 6A illustrates an example of a method for manufacturing a wiring substrate according to an embodiment of the present invention;

FIG. 6B illustrates an example of a method for manufacturing a wiring substrate according to an embodiment of the present invention;

FIG. 6C illustrates an example of a method for manufacturing a wiring substrate according to an embodiment of the present invention;

FIG. 6D illustrates an example of a method for manufacturing a wiring substrate according to an embodiment of the present invention;

FIG. 6E illustrates an example of a method for manufacturing a wiring substrate according to an embodiment of the present invention;

FIG. 7A illustrates an example of a method for manufacturing a wiring substrate according to an embodiment of the present invention;

FIG. 7B illustrates an example of a method for manufacturing a wiring substrate according to an embodiment of the present invention;

FIG. 7C illustrates an example of a method for manufacturing a wiring substrate according to an embodiment of the present invention;

FIG. 8A illustrates an example of a method for manufacturing a wiring substrate according to an embodiment of the present invention;

FIG. 8B illustrates an example of a method for manufacturing a wiring substrate according to an embodiment of the present invention; and

FIG. 8C illustrates an example of a method for manufacturing a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

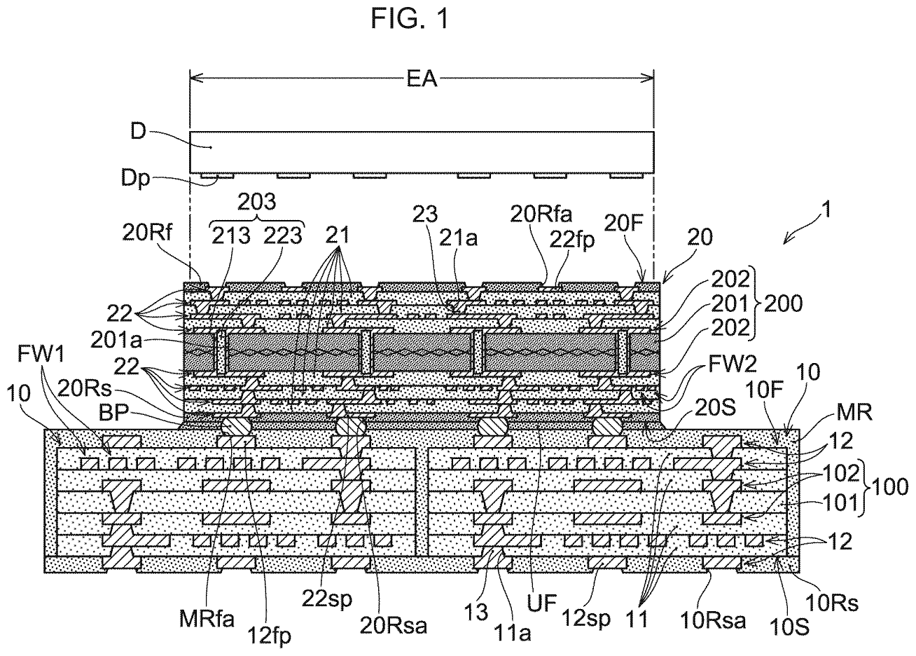

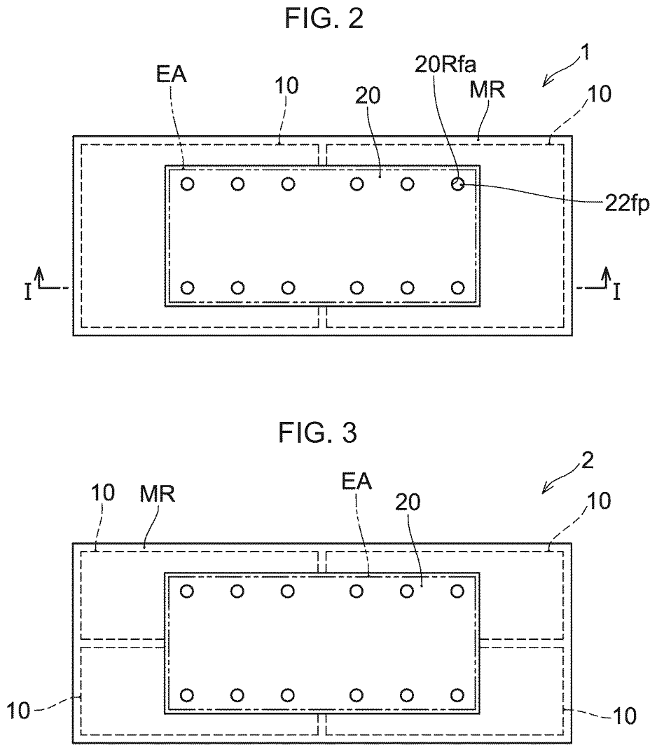

A wiring substrate according to an embodiment of the present invention is described with reference to the drawings. FIG. 1 is a cross-sectional view illustrating a wiring substrate 1 which is an example of a wiring substrate according to an embodiment of the present invention. FIG. 2 is a top view of the wiring substrate 1 illustrated in FIG. 1. The cross-sectional view illustrated in FIG. 1 is a cross-sectional view taken along an I-I line in FIG. 2. A laminated structure, and the number of conductor layers and the number of insulating layers, of the wiring substrate of the present embodiment, as well as a positioning relationship of multiple substrates constituting the wiring substrate, are not limited to the laminated structure of the wiring substrate 1 illustrated in FIG. 1, the number of conductor layers and the number of insulating layers included in the wiring substrate 1, as well as the positioning relationship of the substrates in the wiring substrate 1.

The wiring substrate of the embodiment includes a second substrate, and multiple first substrates, each of which is composed of multiple conductor layers and multiple insulating layers that are alternately laminated. The wiring substrate 1 in the illustrated example includes two first substrates 10 and one second substrate 20. The multiple first substrates 10 each have, as two main surfaces orthogonal to their thickness direction, one surface (10F) and another surface (10S) on an opposite side with respect to the one surface (10F). The second substrate 20 has, as two main surfaces orthogonal to its thickness direction, a first surface (20F) and a second surface (20S) on an opposite side with respect to the first surface (20F). The second substrate 20 is positioned such that the second surface (20S) faces the one surface (10F) of each of the first substrates 10.

In the description of the wiring substrate, the first surface (20F) side of the second substrate 20 is also referred to as “upper” or “upper side,” and the other surface (10S) side of each of the first substrates 10 is also referred to as “lower” or “lower side.” Further, for each of the structural elements of the wiring substrate, a surface facing the first surface (20F) side of the second substrate 20 is also referred to as an “upper surface,” and a surface facing the other surface (10S) side of each the first substrates 10 is also referred to as a “lower surface.”

The first substrates 10 and the second substrate 20 each include alternately laminated insulating layers and conductor layers. Specifically, in the illustrated example, the first substrates 10 each include a core substrate 100, which includes an insulating layer 101 and conductor layers 102 that are respectively formed in contact with two surfaces of the insulating layer 101 that are orthogonal to the thickness direction, as well as four insulating layers 11 and four conductor layers 12 laminated on both sides (upper and lower sides) of the core substrate 100. In the illustrated example, the second substrate 20 includes a core substrate 200, which includes an insulating layer 201 and conductor layers 202 that are respectively formed in contact with two surfaces of the insulating layer 201 that are orthogonal to the thickness direction, as well as six insulating layers 21 and six conductor layers 22 laminated on both sides (upper and lower sides) of the core substrate 200. The core substrate 100 constituting each of the first substrates 10 is also referred to as the first core substrate 100. The insulating layers 11 constituting each of the first substrates 10 are also referred to as the first insulating layers 11, and the conductor layers 12 constituting each of the first substrates 10 are also referred to as the first conductor layers 12. The insulating layer 101 constituting the first core substrate 100 of each of the first substrates 10 is also referred to as the first core insulating layer 101, and the conductor layers 102 constituting the first core substrate 100 of each of the first substrates 10 are also referred to as the first core conductor layers 102. The core substrate 200 constituting the second substrate 20 is also referred to as the second core substrate 200. The insulating layers 21 constituting the second substrate 20 are also referred to as the second insulating layers 21, and the conductor layers 22 constituting the second substrate 20 are also referred to as the second conductor layers 22. The insulating layer 201 constituting the second core substrate 200 of the second substrate 20 is also referred to as the second core insulating layer 201, and the conductor layers 202 constituting the second core substrate 200 of the second substrate 20 are also referred to as the second core conductor layers 202.

In each of the multiple first substrates 10, the first core conductor layers 102 that are respectively formed in contact with the two surfaces of the first core insulating layer 101 constituting the first core substrate 100 are connected by penetrating conductors 103 that penetrate the first core insulating layer 101 in the thickness direction. In each of the first insulating layers 11 constituting each of the first substrates 10, via conductors 13 are formed that penetrate the first insulating layer 11 in the thickness direction and connect the conductor layers (first conductor layers 12, or a first conductor layer 12 and a first core conductor layer 102) that face each other with the first insulating layer 11 interposed therebetween. The second core conductor layers 202 that are respectively formed in contact with the two surfaces of the second core insulating layer 201 constituting the second core substrate 200 of the second substrate 20 are connected by through-hole conductors 203 that penetrate the second core insulating layer 201 in the thickness direction. In each of the second insulating layers 21 constituting the second substrate 20, via conductors 23 are formed that penetrate the second insulating layer 21 in the thickness direction and connect the conductor layers (second conductor layers 22, or a second conductor layer 22 and a second core conductor layer 202) that face each other with the second insulating layer 21 interposed therebetween. The via conductors 13 formed in the first insulating layers 11 are also referred to as the first via conductors 13, and the via conductors 23 formed in the second insulating layers 21 are also referred to as the second via conductors 23.

The penetrating conductors 103 are formed by filling through-holes (101a) formed in the core insulating layer 101 with a conductive material, and have a form of so-called filled vias. The penetrating conductors 103 are integrally formed with the core conductor layers 102. Each through-hole conductor 203 includes a conductor film 213 for conduction, which covers an inner wall of a through hole (201a) formed in the core insulating layer 201, and a filling material 223, such as an insulating resin, that fills a region (hollow space) defined by the conductor film 213. That is, the through-hole conductors 203 each include the conductor film 213 responsible for conductivity and the filling material 223 that fills the inner side of the conductor film 213. The conductor film 213 constituting each of the through-hole conductors 203 is formed integrally with the core conductor layers 202. The first via conductors 13 are formed by filling through holes (11a) formed in the first insulating layers 11 with a conductive material. Each first via conductor 13 is integrally formed with a first conductor layer 12 that is in contact with the upper side of the first insulating layer 11 that the first via conductor 13 penetrates. The second via conductors 23 are formed by filling through holes (21a) formed in the second insulating layers 21 with a conductive material. Each second via conductor 23 is integrally formed with a second conductor layer 22 that is in contact with a surface of the second insulating layer 21 that the second via conductor 23 penetrates, the surface being on an opposite side with respect to the core substrate 200.

The first core insulating layer 101, the first insulating layers 11, the second core insulating layer 201, and the second insulating layers 21 are formed using an insulating resin. Examples of the insulating resin include an epoxy resin, a bismaleimide triazine resin (BT resin), a phenol resin, and the like. The first core insulating layer 101, the first insulating layers 11, the second core insulating layer 201, and the second insulating layers 21 may contain any of a fluororesin, a liquid crystal polymer (LCP), a polytetrafluoroethylene resin (PTFE), a polyester resin (PE), and a modified polyimide resin (MPI).

Examples of conductors constituting the first conductor layers 12, the second conductor layers 22, the first via conductors 13, the second via conductors 23, the penetrating conductors 103, the conductor film 213 of each of the through-hole conductors 203, the first core conductor layers 102, and the second core conductor layers 202 include copper, nickel and the like, and preferably copper is used. In the example illustrated in FIG. 1, the first conductor layers 12, the second conductor layers 22, the first via conductors 13, the second via conductors 23, the conductor film 213, the penetrating conductors 103, the first core conductor layers 102, and the second core conductor layers 202 are each illustrated as having a single-layer structure, but they can each have a multilayer structure. The first conductor layers 12, the core conductor layers 202, the second conductor layers 22, the first via conductors 13, the second via conductors 23, the conductor films 213, the penetrating conductors 103, the first core conductor layers 102, and the second core conductor layers 202 can each have, for example, a multilayer structure including any of a metal foil layer (preferably a copper foil), a metal film layer (preferably a copper film formed by electroless plating or sputtering), and a plating film layer (preferably an electrolytic copper plating film). For example, the second conductor layers 22, the first via conductors 13, the second via conductors 23, the conductor films 213, and the penetrating conductors 103 can each have a two-layer structure including a metal film layer and a plating film layer. For example, the first core conductor layers 102 and the first conductor layers 12 can each have a three-layer structure including a metal foil layer, a metal film layer, and a plating film layer. The second core conductor layers 202 can each have a five-layer structure including a metal foil layer, a metal film layer, a plating film layer, a metal film layer, and a plating film layer.

The conductor layers (the first conductor layers 12, the second conductor layers 22, the first core conductor layers 102, and the second core conductor layers 202) constituting the wiring substrate 1 are each patterned to have predetermined conductor patterns. The second conductor layer 22 constituting the first surface (20F) of the second substrate 20 is formed to have patterns including conductor pads (22fp). The second conductor layer 22 constituting the second surface (20S) of the second substrate 20 is formed to have patterns including conductor pads (22sp). The first conductor layer 12 constituting the one surface (10F) of each of the first substrates 10 is formed to have patterns including conductor pads (12fp). The first conductor layer 12 constituting the other surface (10S) of each of the first substrates 10 is formed to have patterns including conductor pads (12sp).

In the illustration, a solder resist layer (20Rf) formed using, for example, a photosensitive polyimide resin or epoxy resin is laminated on the uppermost second conductor layer 22 of the second substrate 20. Openings (20Rfa) are formed in the solder resist layer (20Rf), and the conductor pads (22fp) are exposed from the openings (20Rfa). That is, the first surface (20F) includes a surface of the solder resist layer (20Rf) and surfaces of the conductor pads (22fp) exposed from the openings (20Rfa). A solder resist layer (20Rs) is laminated on the lower side of the lowermost second conductor layer 22 of the second substrate 20. Openings (20Rsa) are formed in the solder resist layer (20Rs), and the conductor pads (22sp) are exposed from the openings (20Rsa). That is, the second surface (20S) includes a surface of the solder resist layer (20Rs) and surfaces of the conductor pads (22sp) exposed from the openings (20Rsa).

In the wiring substrate 1, the multiple first substrates 10 are physically bonded to each other. Specifically, the two first substrates 10 constituting the wiring substrate 1 are integrated by being sealed with a sealing resin (MR). Gaps between the multiple first substrates 10 are filled with the sealing resin (MR), and further, the sealing resin (MR) covers a side surface and an upper surface (the one surface (10F)) of each of the multiple first substrates 10. Therefore, in the top view of FIG. 2, the multiple first substrates 10 are indicated with dashed lines as being embedded in the sealing resin (MR). As illustrated in FIG. 1, openings (MRfa) are formed in the sealing resin (MR) that covers the one surface (10F) of each of the first substrates 10, and conductor pads (12fp) are exposed from the openings (MRfa). The sealing resin (MR) may contain, for example, a photosensitive epoxy resin, and may also contain a thermoplastic resins such as a fluorine resin, a liquid crystal polymer (LCP), a fluorinated ethylene resin (PTFE), a polyester resin (PE), a modified polyimide resin (MPI), or the like. By integrating the multiple first substrates 10 with the sealing resin (MR), it is thought that the upper surfaces of the multiple first substrates 10 can achieve better flatness, and thus, the connection reliability between the first substrates 10 and the second substrate 20 can be improved.

A solder resist layer (10Rs) is laminated on the lower side of the other surface (10S) of each of the first substrates 10. Openings (10Rsa) are formed in the solder resist layer (10Rs), and the conductor pads (12sp) are exposed from the openings (10Rsa). In the illustrated example, the solder resist layer (10Rs) is formed continuously across the multiple first substrates 10. Specifically, the solder resist layer (10Rs) is formed continuously across the other surfaces (10S) of the two first substrates 10 and the lower surface of the sealing resin (MR) between the two first substrates 10.

The first surface (20F) of the second substrate 20 that constitutes an outermost surface of the wiring substrate 1 is structured as a component mounting surface to which an external electronic component is connected. In the illustrated example, the single second substrate 20 has one component mounting region (EA), and the conductive pads (22fp) are formed in the component mounting region (EA). The conductor pads (22fp) are connected to connection pads (Dp) of an external electronic component (D) when the wiring substrate 1 is in use. In mounting an external electronic component onto the wiring substrate 1, a conductive bonding material (not illustrated), such as solder, is positioned on the exposed upper surfaces of the conductor pads (22fp), and the conductor pads (22fp) are electrically and mechanically connected to the connection pads (Dp) of the external electronic component (D) via the conductive bonding material.

Examples of electronic components (D) that can be mounted on the wiring substrate 1 include electronic components such as active components such as semiconductor integrated circuit devices and transistors. Specific examples of electronic components (D) that can be mounted on the wiring substrate 1 include integrated circuits such as logic chips incorporating logic circuits, processing devices such as MPUs (Micro Processor Units), and memory elements such as HBMs (High Bandwidth Memory).

The conductor pads (22sp) constituting the second surface (20S) of the second substrate 20 are mechanically and electrically connected to the conductor pads (12fp) constituting the one surface (10F) of each of the multiple first substrates 10 via conductor bumps (BP). That is, the single second substrate 20 is connected to the multiple first substrates 10 so as to span across the first substrates 10. With such a structure, it is thought that a stress that can act on the second substrate 20 during mounting of an external electronic component or the like can be effectively distributed among the multiple first substrate 10, and occurrence of a defect due to localized stress concentration (for example, a defect in a connecting part between a first substrate 10 and the second substrate 20) can be suppressed. An underfill material (UF) such as an epoxy resin or a polyimide resin is filled between the second surface (20S) of the second substrate 20 and the one surface (10F) of each of the first substrates 10 (specifically, between the lower surface of the solder resist layer (20Rs) and the upper surface of the sealing resin (MR)). By filling the underfill material (UF) between the second substrate 20 and each of the first substrates 10, it is thought that rigidity against a physical stress (a thermal stress or a physical external force) that can act to the wiring substrate 1 is improved, and therefore, the reliability of the connection between the second substrate 20 and each of the first substrates 10 is improved.

The other surface (10S) of each of the multiple first substrates 10, which is on an opposite side with respect to the first surface (20F) of the second substrate 20 (which is a component mounting surface of the wiring substrate 1) can be a connection surface that is connected to an external element such as an external wiring substrate (for example, a motherboard of any electrical device) when the wiring substrate 1 is mounted on the external element. Therefore, in using the wiring substrate 1, the conductor pads (12sp) can be connected to any substrate, electrical component, mechanical component, or the like.

In the wiring substrate of the embodiment, the second substrate having the component mounting region is connected to the multiple first substrates. Compared to a case where a wiring substrate include the second substrate and a single first substrate, when the wiring substrate includes multiple first substrates, dimensions of each of the multiple first substrates in a planar direction can be reduced. When the dimensions of each first substrate in a planar direction are large, it is thought that a degree of warping that can occur in the first substrate due to differences in thermal expansion coefficients between the structural elements of the first substrate is relatively large. When the degree of warping of each first substrate is large, the connection reliability between the first substrate and the second substrate decreases. Here, “dimensions in a planar direction” means dimensions of an object when the object is viewed along a direction parallel to the thickness direction of the wiring substrate (in plan view). In the wiring substrate of the embodiment, with the structure in which the wiring substrate includes the multiple first substrates, it is thought that, compared to the case where the wiring substrate includes a single first substrate, the dimensions of each of the multiple first substrates in a planar direction can be reduced, and accordingly, the degree of warping that can occur in each first substrate is relatively small. A highly reliable connection between each first substrate and the second substrate can be achieved.

Further, a wiring substrate including multiple first substrates can be produced with good yield. In a structure in which the wiring substrate includes a single first substrate, when a defect occurs in a portion of the first substrate during the production of the wiring substrate, the entire single first substrate is replaced. In contrast, in a wiring substrate including multiple first substrates, when a defect occurs in a first substrate, only the first substrate containing the defective portion among the multiple first substrates can be removed before sealing the first substrates. A first substrate in which no defect has occurred can be used as-is to manufacture the wiring substrate. Therefore, it is thought that the wiring substrate of the embodiment is suitable for production with good yield, and further, loss cost per defect occurrence in the production is also relatively low. The multiple first substrates included in the wiring substrate of the embodiment have substantially the same thickness (a shortest distance between the one surface (10F) and the other surface (10S)). Further, the multiple first substrates can have the same dimensions in a planar direction, the same number of insulating layers and conductor layers included, and the same materials constituting the insulating layers and the conductor layers.

In the wiring substrate 1, the first conductor layers 12 of each of the first substrates 10 and the second conductor layers 22 of the second substrate 20 each include wirings formed according to mutually different wiring rules. The first conductor layers 12 of each of the first substrates 10 can include wirings (FW1), and the second conductor layers 22 of the second substrate 20 can include wirings (FW2) that are high-density wirings with relatively small pattern widths and inter-pattern distances. Specifically, a minimum pattern width of the wirings (FW1) that can be included in the first conductor layers 12 of each of the first substrates 10 can differ from a minimum pattern width of the wirings (FW2) that can be included in the second conductor layers 22 of the second substrate 20. The wirings (FW2) included in the second substrate 20 can have pattern widths that are smaller than the minimum pattern width of the wirings (FW1) that can be included in the first conductor layers 12 in each of the first substrates 10. A minimum inter-pattern distance of the wirings (FW1) that can be included in the first conductor layers 12 of each of the first substrates 10 can differ from a minimum inter-pattern distance of the wirings (FW2) that can be included in the second conductor layers 22 of the second substrate 20. The wirings (FW2) included in the second substrate 20 can have inter-pattern distances that are smaller than the minimum inter-pattern distance of the wirings (FW1) that are included in the first conductor layers 12 in each of the first substrates 10. Specifically, for example, the minimum pattern width of the wirings (FW2) is 12 μm or less, and the minimum inter-pattern distance of the wirings (FW2) is 15 μm or less. When the second substrate 20 has the fine wirings (FW2), it may be possible to provide wirings with more suitable characteristics in a circuit that connects to an external electronic component (D).

When the second conductor layers 22 are formed to include the wirings (FW2) that are formed with fine pattern widths and inter-pattern distances as described above, it may be preferable that the second via conductors 23 are also formed with a fine pitch. In this case, small-diameter through holes (21a) are formed in the second insulating layers 21. Therefore, although the second insulating layers 21 can contain an inorganic filler such as fine particles of silica (SiO2), alumina, mullite, or the like, it may be preferable that the second insulating layers 21 do not contain an inorganic filler in order to facilitate the formation of small-diameter through holes (21a). Further, when the second conductor layers 22 include the wirings (FW2), it is preferable that the second insulating layers 21 do not contain a core material (reinforcement material) formed of glass fiber, aramid fiber, or the like.

The second conductor layers 22 that can include the wirings (FW2) are formed to each have a thickness of, for example, 10 μm or more and 25 μm or less. The second insulating layers 21 in the second substrate 20 are formed to each have a thickness of, for example, 15 μm or more and 40 μm or less. The first conductor layers 12 that can include the wirings (FW1) are formed to each have a thickness of, for example, 15 μm or more and 40 μm or less. The first insulating layers 11 in each of the first substrates 10 are formed to each have a thickness of, for example, 40 μm or more and 100 μm or less.

In the wiring substrate 1 in the illustrated example, the second substrate 20 includes the core substrate 200 and has a relatively large thickness. The core substrate 200 includes a relatively highly rigid core insulating layer 201 containing a core material (reinforcing material) made of glass fiber, aramid fiber, or the like. Therefore, in the second substrate 20, occurrence of warping is suppressed. In the second substrate 20, when the second insulating layers 21 and the second conductor layers 22 are formed in equal numbers on the upper and lower sides of the core substrate 200, it is thought that the warping in the second substrate 20 is further suppressed.

The thickness of the second substrate 20 (the shortest distance between the first surface (20F) and the second surface (20S)) is preferably relatively large and preferably greater than the thickness of each of the first substrates 10 (the shortest distance between the one surface (10F) and the other surface (10S)). It is thought that a stress acting on the second substrate 20 during mounting of an external electronic component (D) onto the component mounting surface is absorbed by the second substrate 20 before reaching a connecting part between the second substrate 20 and a first substrate 10, and thus, occurrence of a defect at the connecting part between the second substrate 20 and the first substrate 10 can be suppressed.

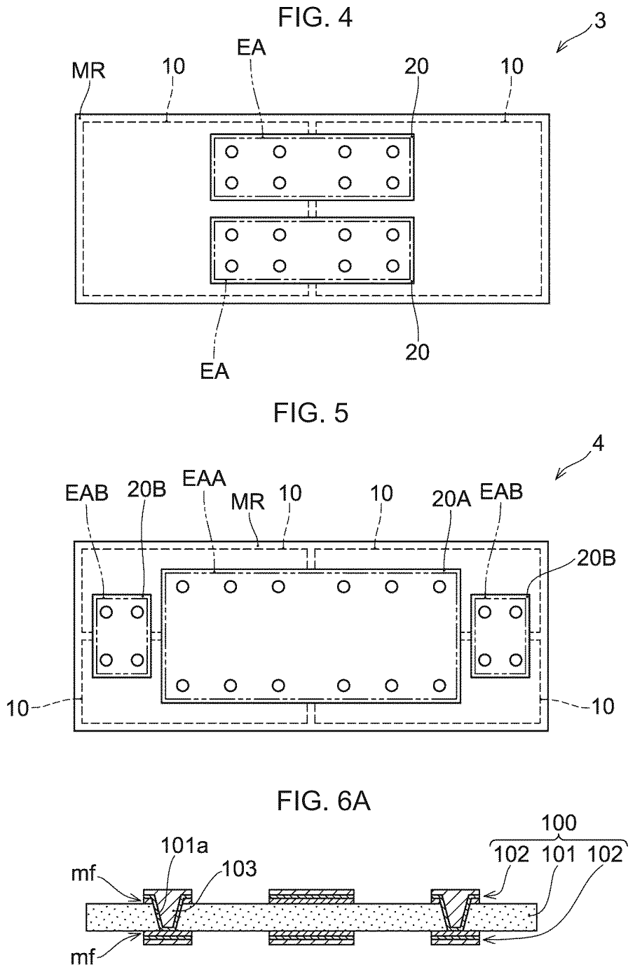

Next, with reference to FIGS. 3 to 5, other examples of the wiring substrate of the embodiment are described. Similar to FIG. 2, FIGS. 3 to 5 each illustrate a top view of a wiring substrate. In the examples illustrated in FIGS. 3 to 5, a positional relationship between first substrates 10 and second substrates 20 differs from that in the example illustrated in FIG. 2. In a wiring substrate 2 illustrated in FIG. 3, a wiring substrate 3 illustrated in FIG. 4, and a wiring substrate 4 illustrated in FIG. 5, multiple first substrates 10 are integrated with a sealing resin (MR), similar to the wiring substrate 1 described with reference to FIGS. 1 and 2. Therefore, in FIGS. 3, 4, and 5, the upper surfaces of the first substrates 10 are covered with the sealing resin (MR), and the first substrates 10 are indicated with dashed lines as being embedded in the sealing resin (MR).

The wiring substrate 2 illustrated in FIG. 3 includes a single second substrate 20 and four first substrates 10. In the wiring substrate 2, which includes a larger number of first substrates 10 than the wiring substrate 1, the dimensions of each of the first substrates 10 in a planar direction can be further reduced, and the degree of warping that can occur in each of the first substrates 10 can be further suppressed. Therefore, in the wiring substrate 2, the connection reliability between the first substrates 10 and the second substrate 20 can be further improved. In the wiring substrate 2, the single second substrate 20 is connected to all of the multiple (four) first substrates 10 included in the wiring substrate 2 so as to span across the first substrates 10. With such a structure, as described above with respect to the wiring substrate 1, it is thought that a stress that can act on the second substrate 20 can be effectively distributed among the multiple first substrates 10, and occurrence of a defect due to localized stress concentration can be suppressed.

The wiring substrate of the embodiment may include a different number of second substrates 20 from the wiring substrate 1 in the example illustrated in FIG. 2 and the wiring substrate 2 in the example illustrated in FIG. 3. That is, the wiring substrate of the embodiment may include multiple second substrates 20. The wiring substrate 3 in the example illustrated in FIG. 4 includes multiple (two) second substrates 20. Further, in the wiring substrate 3, multiple (two) first substrates 10 are connected to each of the multiple second substrates 20. The multiple second substrates 20 included in the wiring substrate 3 have substantially the same thickness. Further, the multiple second substrates 20 can have the same dimensions in a planar direction, the same number of insulating layers and conductor layers included, and the same materials constituting the insulating layers and the conductor layers.

In a structure in which a single second substrate 20 is connected to multiple first substrates 10, as in the wiring substrate 1 and the wiring substrate 2 described above, when the wiring substrate includes multiple component mounting regions (EA), all of the multiple component mounting regions (EA) are provided on the single second substrate 20, and therefore, dimensions of the second substrate 20 in a planar direction may increase. With the increase in the dimensions in a planar direction, a degree of warping that can occur in the second substrate can increase. In the illustrated wiring substrate 3, with the structure that includes the multiple second substrates 20, the multiple second substrates 20 can be respectively realized with sizes corresponding to sizes of the multiple component mounting regions (EA). Therefore, it is thought that the dimensions of each of the multiple second substrates 20 in a planar direction can be reduced, and the degree of warping that occurs in each second substrate 20 can be kept relatively small. It is thought that the connection reliability between the second substrates 20 and the first substrates 10, as well as the connection reliability between the second substrates 20 and the external electronic components can be improved.

Further, as described above with respect to the first substrates 10 in the wiring substrate 1 and the wiring substrate 2, in a structure in which a wiring substrate includes multiple second substrates 20, when a defect occurs in a second substrate 20, the wiring substrate can be manufactured by replacing only the second substrate 20 that contains the defective portion among the multiple second substrates 20. Therefore, it is thought that the wiring substrate 3 that includes the multiple first substrates 10 and the multiple second substrates 20 is even more suitable for production with low loss cost per defect occurrence and good yield. Further, when a second substrate 20 includes fine wirings (FW2), formation of relatively fine wirings (FW2) may require a high technical standard to be achieved in manufacturing the second substrate 20, which may result in a decrease in yield. However, in a wiring substrate that includes multiple second substrates 20, the dimensions of each of the second substrates 20 can be suppressed as described above, and therefore, a range in which the fine wirings (FW2) are formed is also limited, and the possibility of a decrease in yield in manufacturing the second substrates 20 is reduced.

The wiring substrate 3 in the example illustrated in FIG. 4 is an example in which the multiple (two) second substrates 20 have substantially the same dimensions in a planar direction and respectively include component mounting regions (EA) that have substantially the same dimensions. However, the multiple second substrates 20 may have different dimensions in a planar direction and may respectively include component mounting regions (EA) that have different dimensions. The wiring substrate 4 illustrated in FIG. 5 includes four first substrates 10 and three second substrates (20A, 20B). Among the three second substrates (20A, 20B) included in the wiring substrate 4, the two second substrates (20B) have the same dimensions, while the second substrate (20A) has different dimensions from the second substrates (20B). Further, a component mounting region (EAA) included in the second substrate (20A) is different in dimensions from component mounting regions (EAB) that are respectively included in the second substrates (20B). In this way, with the structure in which the second substrates (20A, 20B) having different dimensions respectively include the component mounting regions (EAA, EAB) that have different dimensions, multiple external electronic components having different dimensions can be respectively mounted on the wiring substrate with appropriate dedicated areas.

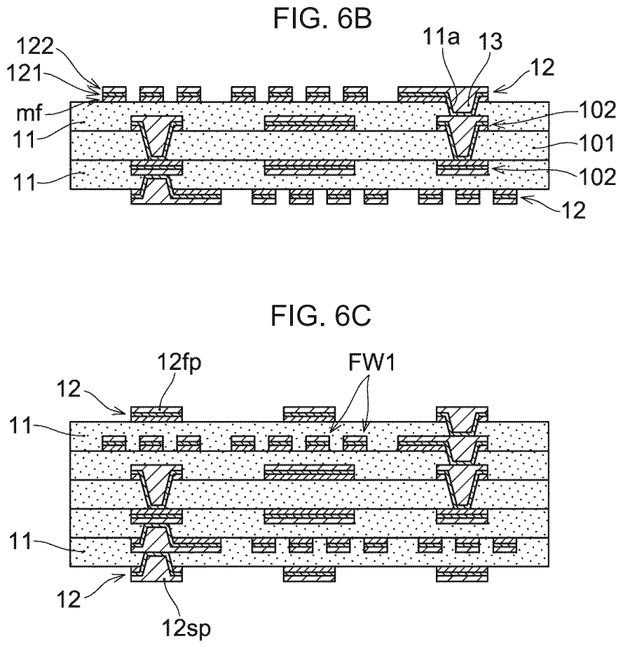

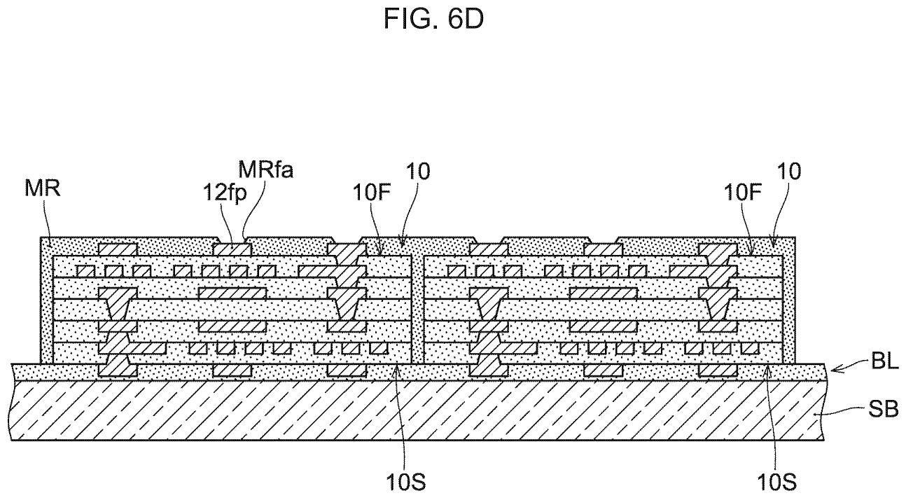

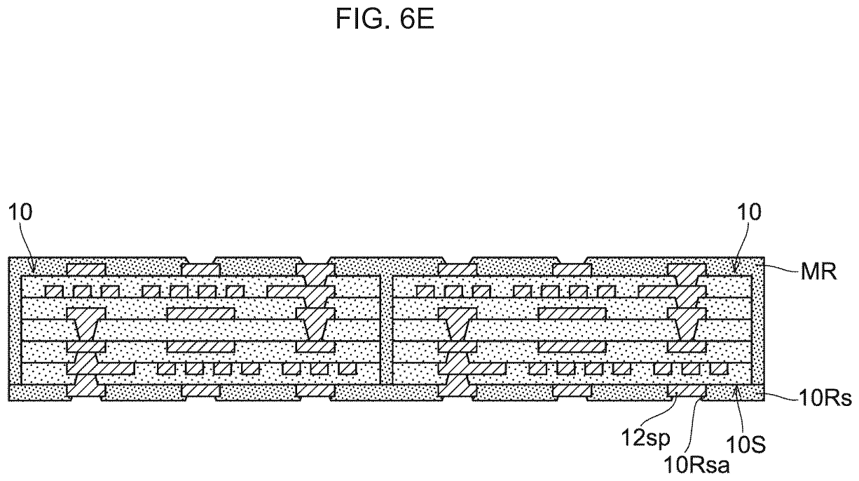

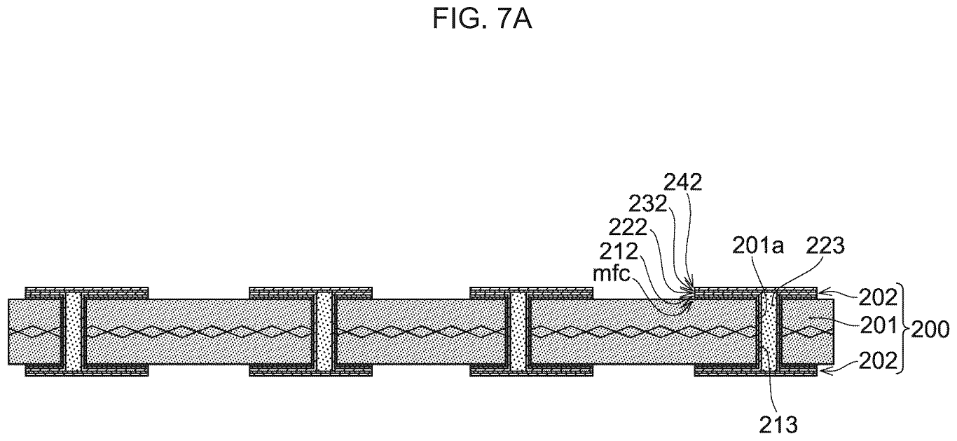

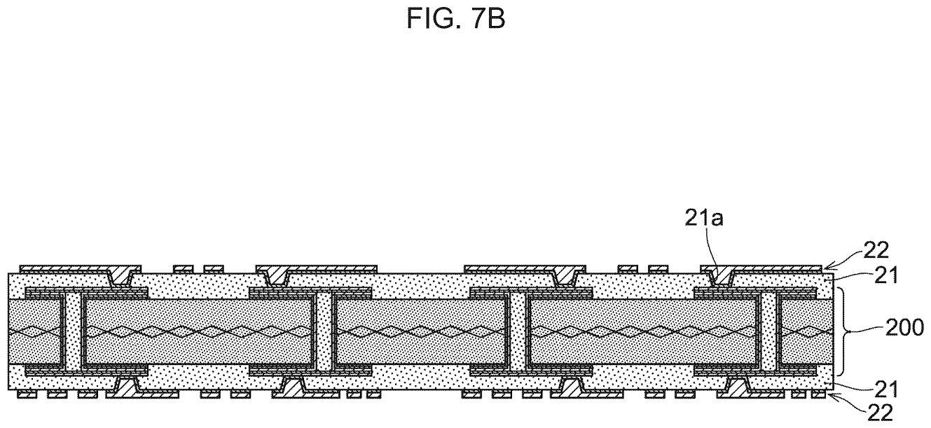

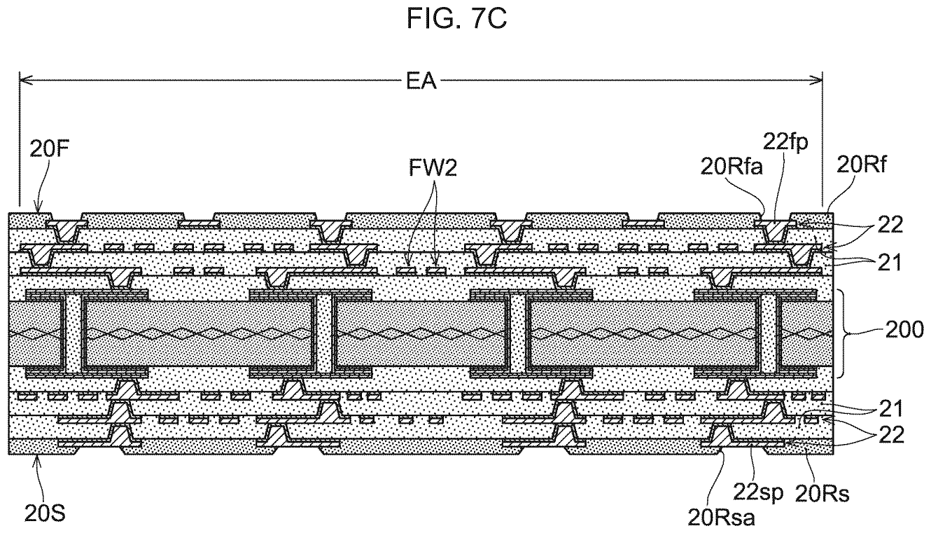

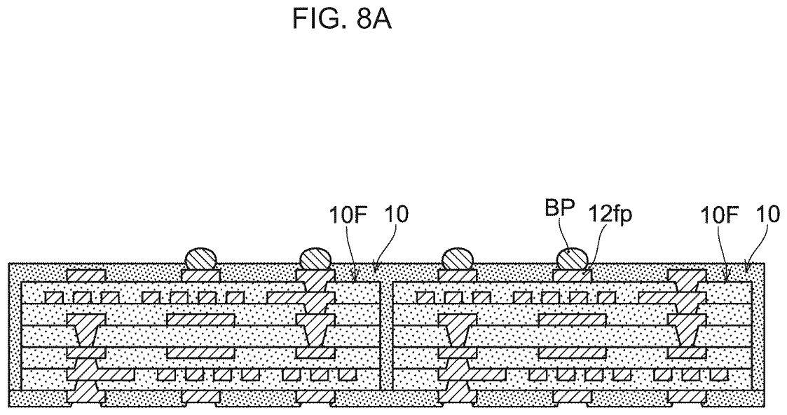

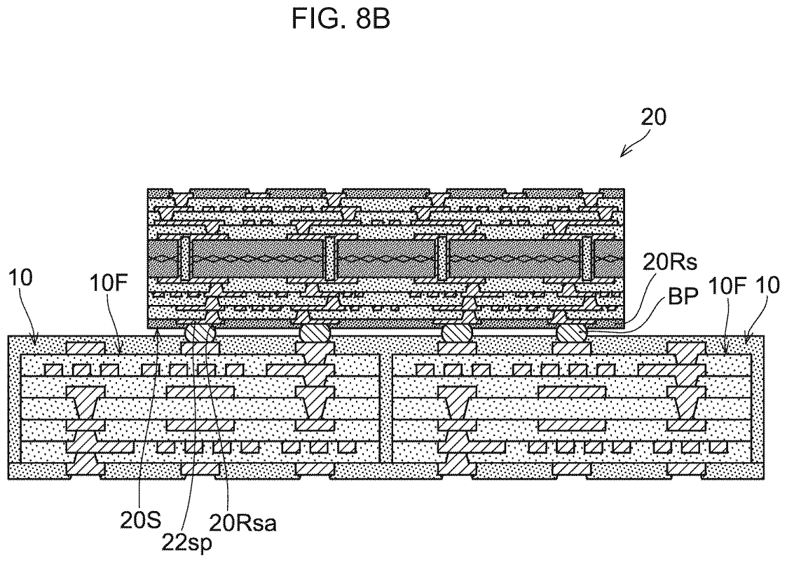

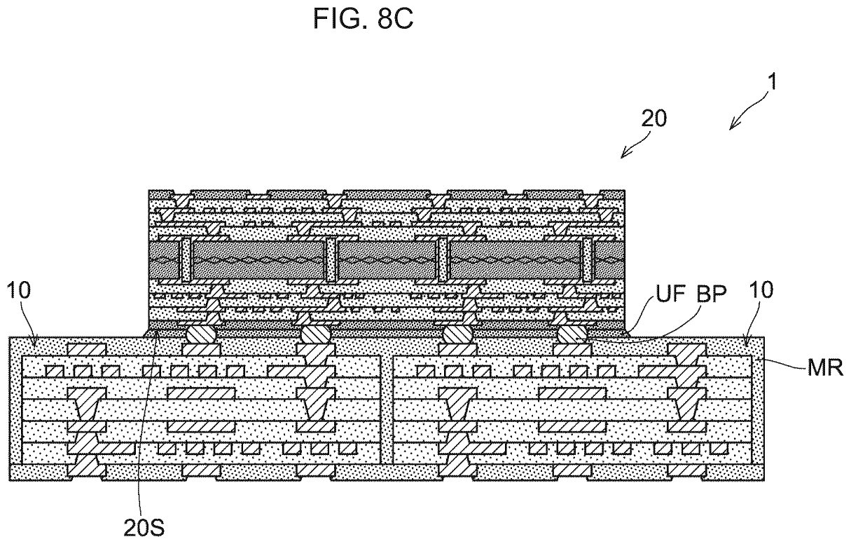

Next, with reference to FIGS. 61 to 6E, 7A to 7C, and 8A to 8C, a method for manufacturing the wiring substrate of the embodiment is described using a case where the wiring substrate 1 illustrated in FIG. 1 is manufactured as an example. Structural elements formed in the manufacturing method to be described below can be formed using the materials exemplified as the materials of the corresponding structural elements in the description of the wiring substrate 1 in FIG. 1, unless otherwise specified. Further, among FIGS. 6A to 6E, 7A to 7C, and 8A to 8C to be referenced below, in FIGS. 6A to 6C and 7A to 7C, each conductor layer is depicted as having a metal foil layer, a metal film layer, and a plating film layer, which are structural elements of the conductor layer, whereas in FIGS. 6D to 6E and 8A to 8C, each conductor layer is depicted as having a single layer, similar to that in FIG. 1.

The method for manufacturing the wiring substrate 1 includes preparing multiple first substrates 10, preparing a second substrate 20, and connecting the multiple first substrates 10 and the second substrate 20. First, with reference to FIGS. 6A to 6E, the preparation of the first substrates 10 is described. In the description with reference to FIGS. 6A to 6C, a side closer to the first core insulating layer 101 of the first core substrate 100 is referred to as “lower,” “inner,” “lower side,” or “inner side,” while a side farther from the first core insulating layer 101 is referred to as “upper,” “outer,” “upper side,” or “outer side.” Therefore, of each element constituting a first substrate 10, a surface facing the first core insulating layer 101 is referred to as a “lower surface,” and a surface facing an opposite side with respect to the first core insulating layer 101 is also referred to as an “upper surface.”

First, as illustrated in FIG. 6A, the first core substrate 100 is formed. For example, a laminated (such as a double-sided copper-clad laminate) is prepared, which includes the first core insulating layer 101 made of an insulating resin such as an epoxy resin, and metal foils (mf) provided on both surfaces of the first core insulating layer 101. The through holes (101a) for the penetrating conductors 103 are formed by laser processing, and then, the first core conductor layers 102 and the penetrating conductors 103 are formed using a subtractive method. The penetrating conductors 103 are formed as so-called filled vias by filling the through holes (101a) with a conductive material.

Next, as illustrated in FIG. 6B, a first insulating layer 11 is formed covering the surface of the first core conductor layer 102 and the first core insulating layer 101 exposed from the patterns of the first core conductor layer 102, and subsequently, the first via conductors 13 penetrating the first insulating layer 11, and the first conductor layer 12 on the first insulating layer 11, are integrally formed using a subtractive method. As the first insulating layer 11, for example, a film-like insulating resin containing an epoxy resin, a phenol resin, or the like can be used.

Specifically, a first insulating layer 11 having a metal foil (mf) on one surface (upper surface) is laminated, and the through-holes (11a) are formed at formation positions of the first via conductors 13 in the first insulating layer 11, for example, by irradiation with CO₂ laser. Next, a metal film layer 121 is formed on inner walls of the through holes (11a) and the surface of the metal foil (mf) by electroless plating or sputtering. A plating film layer 122 is formed on the metal film layer 121 by electrolytic plating using the metal film layer 121 as a power feeding layer. The through holes (11a) are completely filled with the electrolytic plating film 122, and the first via conductors 13 are formed. Next, for example, a dry film resist containing a photosensitive epoxy resin is adhered to the upper surface of the electrolytic plating film 122, and an etching resist is formed having openings corresponding to conductor patterns of a first conductor layer 12 formed on the first insulating layer 11. The plating film layer 122, the metal film layer 121, and the metal foil (mf) exposed in the openings of the etching resist are removed by etching. As a result, as illustrated in FIG. 6B, a first conductor layer 12 is formed having a three-layer structure formed of the metal foil (mf), the metal film layer 121, and the plating film layer 122.

Next, as illustrated in FIG. 6C, processes similar to the lamination of the first insulating layer 11 and the formation of the first via conductors 13 and conductor layer 12 are repeated, and a desired number of first insulating layers 11 and first conductor layers 12 are laminated. The outermost first conductor layers 12 are formed to have patterns including the conductor pads (12fp, 12sp). Further, any of the first conductor layers 12 can be formed to include the wirings (FW1).

Next, as illustrated in FIG. 6D, a support body (SB) provided with an adhesive layer (BL) on a surface on one side in its thickness direction is prepared, and multiple (two) first substrates 10 having substantially the same thickness are placed on the support body (SB) such that the other surface (10S) is in contact with the adhesive layer (BL). The multiple first substrates 10 are positioned with a gap between each other. For the support body (SB), for example, a prepreg formed by impregnating a core material such as glass fiber with a resin material such as epoxy resin, a metal plate containing copper or the like, or a plate-like body made of ceramics or glass can be used. The adhesive layer (BL) is preferably made of a material that can exhibit stronger adhesion to the support body (SB) than to the other surface (10S) of each of the first substrates 10.

Next, for example, a resin material containing a photosensitive epoxy resin is injected in a fluid state into a frame (not illustrated) surrounding a space that includes a region in which the multiple first substrates 10 are positioned. The injected resin material fills gaps between the multiple first substrates 10 and completely covers exposed surfaces of the multiple first substrates 10. After the resin material is cured, the frame is removed, and the multiple first substrates 10 are integrated by the cured sealing resin (MR). The openings (MRfa) exposing the conductor pads (12fp) are formed in the sealing resin (MR).

Next, after the support body (SB) and the adhesive layer (BL) are removed from the multiple first substrates 10 and the sealing resin (MR), the solder resist layer (10Rs) with the openings (10Rsa) exposing the conductor pads (12sp) is formed on the surfaces exposed by the removal of the support body (SB) and the adhesive layer (BL) (the other surfaces (10S) of the first substrates 10 and the surface of the sealing resin (MR)). As illustrated in FIG. 6E, a state is formed in which the multiple first substrates 10 are integrated by the sealing resin (MR), and the preparation of the first substrates 10 is completed.

In the method for manufacturing the wiring substrate of the embodiment, the multiple first substrates 10 having substantially the same thickness are prepared during the preparation of the first substrates 10. Therefore, as described above in the description of the wiring substrate, when a defect occurs in any of the multiple first substrates 10, it is possible to remove only the first substrate containing the defective portion before sealing the first substrates. A first substrate in which no defect has occurred can be used as is, and thus, the wiring substrate can be manufactured with good yield. Further, the multiple first substrates 10 each having relatively small dimensions in a planar direction can be manufactured, and thus, the degree of warping that can occur in each of the multiple first substrates 10 is relatively small, allowing the first substrates 10 and the second substrate 20 to be more reliably connected.

Next, with reference to FIGS. 7A to 7C, the preparation of the second substrate 20 is described. First, as illustrated in FIG. 7A, the second core substrate 200 is prepared. In describing the preparation of the second substrate 20, a side closer to the second core insulating layer 201 of the second core substrate 200 is referred to as “lower” or “lower side,” while a side farther from the second core insulating layer 201 is referred to as “upper” or “upper side.” Therefore, of each element constituting the second substrate 20, a surface facing the second core insulating layer 201 is referred to as a “lower surface,” and a surface facing an opposite side with respect to the second core insulating layer 201 is referred to as an “upper surface.”

In preparing the second core substrate 200, for example, a double-sided copper-clad laminate is prepared, which includes the second core insulating layer 201 made of glass epoxy resin, and copper foils (mfc) laminated on both surfaces of the second core insulating layer 201. The through holes (201a) are formed in the double-sided copper-clad laminate, for example, by drilling. Next, a metal film layer 212 is formed by an electroless plating film on inner walls of the through holes (201a) and on the upper surfaces of the copper foils, and a plating film layer 222 is formed on the metal film layer 212 by electrolytic plating using the metal film layer 212 as a power feeding layer. As a result, the conductor film 213 is formed, which has a two-layer structure including the metal film layer 212 and the plating film layer 222, and covers the inner walls of the through holes (201a).

Next, the inner side of the conductor film 213 is filled with the filling material 223, such as an epoxy resin. After the filling material 223 is solidified, a metal film layer 232 and a plating film layer 242 are further formed on the upper surfaces of the filling material 223 and the plating film layer 222. As a result, the second core conductor layers 202 each having a five-layer structure including the metal foil layer (mfc), the metal film layer 212, the plating film layer 222, the metal film layer 232, and the plating film layer 242 are respectively formed on both sides of the second core insulating layer 201. Then, the second core substrate 200 having predetermined conductor patterns is obtained by patterning the second core conductor layers 202 using a subtractive method.

Next, as illustrated in FIG. 7B, the second insulating layers 21 are respectively formed on both surfaces of the second core substrate 200, and the second conductor layers 22 are respectively formed on the second insulating layers 21. For example, the second insulating layers 21 are each formed by thermocompression bonding a film-like insulating resin onto the second core substrate 200. The second conductor layers 22 are formed using any method for forming conductor patterns, such as a semi-additive method, at the same time as the via conductors 23 filling the through holes (21a), which can be formed, for example, using laser, in the second insulating layers 21.

Next, as illustrated in FIG. 7C, the formation of the second insulating layers 21 and the second conductor layers 22 is repeated a desired number of times on upper sides of both sides of the second core substrate 200. The solder resist layer (20Rf) having the openings (20Rfa) exposing the conductor pads (22fp) is formed on the outermost second conductor layer 22 and second insulating layer 21 on one side of the second core substrate 200. The solder resist layer (20Rs) having the openings (20Rsa) exposing the conductor pads (22sp) is formed on the outermost second conductor layer 22 and second insulating layer 21 on the other side of the second core substrate 200. The formation of the second substrate 20 is completed, which has a first surface (20F) having a component mounting region (EA) and a second surface (20S) on an opposite side with respect to the first surface (20F). The second conductor layers 22 are formed to include, as their conductor patterns, the wirings (FW2), which are relatively fine wirings.

Next, with reference to FIGS. 8A to 8C, the connection between the first substrates 10 and the second substrate 20 is described. First, as illustrated in FIG. 8A, the conductor bumps (BP), made of a bonding material such as solder, are formed on the conductor pads (12fp) constituting the one surface (10F) of each of the multiple first substrates 10.

Next, as illustrated in FIG. 8B, the prepared second substrate 20 is connected to the first substrates 10 via the conductor bumps (BP). Specifically, the second substrate 20 is positioned such that its second surface (20S) faces the one surface (10F) of each of the first substrates 10, and the conductor pads (22sp) exposed in the openings (20Rsa) of the solder resist layer (20Rs) constituting the second surface (20S) are connected to the conductor bumps (BP).

Next, as illustrated in FIG. 8C, the underfill material (UF) is filled and then cured in a gap between the upper surface of the sealing resin (MR) (covering the one surfaces (10F) of the first substrates 10) and the second surface (20S) of the second substrate 20, which are interconnected via the conductor bumps (BP). The manufacture of the wiring substrate 1 is completed.

The wiring substrate of the embodiment is not limited to those having the structures illustrated in the drawings and those having the structures, shapes, and materials exemplified herein. The wiring substrate of the embodiment can include a first substrate and a second substrate having any laminated structures, and the first substrate and the second substrate can each include any number of conductor layers and insulating layers.

The wiring substrate of the embodiment can include any number of two or more first substrates, and any number of second substrates.

The method for manufacturing the wiring substrate of the embodiment is not limited to the method described with reference to FIGS. 6A to 6E, 7A to 7C, and 8A to 8C, and the conditions, processing order, and the like of the method can be changed as desired. Further, it is also possible that a specific process is omitted or another process is added. In the method for manufacturing the wiring substrate of the embodiment, it is sufficient that the second surface of the second substrate is connected to the one surfaces of the multiple first substrates via the conductor bumps, and, for example, a plating layer including a nickel layer and a tin layer may be formed on the surfaces of the conductor pads.

Japanese Patent Application Laid-Open Publication No. 2012-160701 describes a semiconductor mounting member. The semiconductor mounting member is composed of a single first substrate and a single second substrate. The second substrate is connected to the first substrate via bumps. A semiconductor element is connected on a surface of the second substrate on an opposite side with respect to the first substrate.

In the semiconductor mounting member described in Japanese Patent Application Laid-Open Publication No. 2012-160701, one second substrate is connected to one first substrate. When dimensions of the semiconductor mounting member in a planar direction are relatively large, it is thought that there is a concern that manufacturing yield may decrease, and a degree of warping of the semiconductor mounting member may increase.

A wiring substrate according to an embodiment of the present invention includes at least one first substrate that has one surface and another surface on an opposite side with respect to the one surface, and includes first conductor layers and first insulating layers alternately laminated on both surfaces of a first core substrate; and at least one second substrate that has a first surface provided with a component mounting region and a second surface on an opposite side with respect to the first surface, and includes second conductor layers and second insulating layers alternately laminated on both surfaces of a second core substrate. The at least one first substrate includes multiple first substrates that have substantially the same thickness, and the second surface of the at least one second substrate is connected, via conductor bumps, to the one surface of each of the multiple first substrates.

A method for manufacturing a wiring substrate according to another embodiment of the present invention includes preparing at least one first substrate that has one surface and another surface on an opposite side with respect to the one surface, and includes first conductor layers and first insulating layers alternately laminated on both surfaces of a first core substrate; preparing at least one second substrate that has a first surface provided with a component mounting region and a second surface on an opposite side with respect to the first surface, and includes second conductor layers and second insulating layers alternately laminated on both surfaces of a second core substrate; and connecting the at least one second substrate and the at least one first substrate via conductor bumps. In the preparing of the at least one first substrate, multiple first substrates having substantially the same thickness are prepared, and the one surface of each of the multiple first substrates is connected to the second surface of the at least one second substrate.

According to an embodiment of the present invention, a wiring substrate can be provided that can be produced with good yield and has a small degree of warping.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a plurality of first substrates each comprising a first core substrate, a plurality of first conductor layers and a plurality of first insulating layers;
at least one second substrate each comprising a second core substrate, a plurality of second conductor layers and a plurality of second insulating layers; and
a plurality of conductor bumps connecting a surface of each of the first substrates to a second surface of the at least one second substrate on an opposite side with respect to a first surface of the at least one second substrate such that the first surface of the at least one second substrate has a component mounting region,
wherein the first substrates have substantially a same thickness and are formed such that the first conductor layers and the first insulating layers are laminated on a first surface of the first core substrate and on a second surface of the first core substrate on an opposite side with respect to the first surface of the first core substrate, and the at least one second substrate is formed such that the second conductor layers and the second insulating layers are laminated on a first surface of the second core substrate and on a second surface of the second core substrate on an opposite side with respect to the first surface of the second core substrate.

2. The wiring substrate according to claim 1, wherein the at least one second substrate comprises a plurality of second substrates having substantially a same thickness such that the plurality of second substrates is connected to the plurality of first substrates.

3. The wiring substrate according to claim 2, wherein the plurality of second substrates includes at least two second substrates having different dimensions from each other in a plan view.

4. The wiring substrate according to claim 1, wherein the at least one second substrate has a thickness greater than a thickness of each of the first substrates.

5. The wiring substrate according to claim 1, further comprising:
a sealing resin integrating the plurality of first substrates.

6. The wiring substrate according to claim 1, wherein the first conductor layers in each of the first substrates include a plurality of wirings having a minimum pattern width that is different from a minimum pattern width of a plurality of wirings formed in the second conductor layers of the at least one second substrate.

7. The wiring substrate according to claim 6, wherein the minimum pattern width of the wirings formed in the second conductor layers of the at least one second substrate is smaller than the minimum pattern width of the wirings formed in the first conductor layers in each of the first substrates.

8. The wiring substrate according to claim 2, wherein the at least one second substrate has a thickness greater than a thickness of each of the first substrates.

9. The wiring substrate according to claim 2, further comprising:
a sealing resin integrating the plurality of first substrates.

10. The wiring substrate according to claim 2, wherein the first conductor layers in each of the first substrates include a plurality of wirings having a minimum pattern width that is different from a minimum pattern width of a plurality of wirings formed in the second conductor layers of the at least one second substrate.

11. The wiring substrate according to claim 10, wherein the minimum pattern width of the wirings formed in the second conductor layers of the at least one second substrate is smaller than the minimum pattern width of the wirings formed in the first conductor layers in each of the first substrates.

12. The wiring substrate according to claim 3, wherein the at least one second substrate has a thickness greater than a thickness of each of the first substrates.

13. The wiring substrate according to claim 3, further comprising:
a sealing resin integrating the plurality of first substrates.

14. The wiring substrate according to claim 3, wherein the first conductor layers in each of the first substrates include a plurality of wirings having a minimum pattern width that is different from a minimum pattern width of a plurality of wirings formed in the second conductor layers of the at least one second substrate.

15. The wiring substrate according to claim 14, wherein the minimum pattern width of the wirings formed in the second conductor layers of the at least one second substrate is smaller than the minimum pattern width of the wirings formed in the first conductor layers in each of the first substrates.

16. The wiring substrate according to claim 4, further comprising:
a sealing resin integrating the plurality of first substrates.

17. The wiring substrate according to claim 4, wherein the first conductor layers in each of the first substrates include a plurality of wirings having a minimum pattern width that is different from a minimum pattern width of a plurality of wirings formed in the second conductor layers of the at least one second substrate.

18. The wiring substrate according to claim 17, wherein the minimum pattern width of the wirings formed in the second conductor layers of the at least one second substrate is smaller than the minimum pattern width of the wirings formed in the first conductor layers in each of the first substrates.

19. A method for manufacturing a wiring substrate, comprising:
preparing a plurality of first substrates each comprising a first core substrate, a plurality of first conductor layers and a plurality of first insulating layers;
preparing at least one second substrate each comprising a second core substrate, a plurality of second conductor layers and a plurality of second insulating layers; and
connecting a surface of each of the first substrates to a second surface of the at least one second substrate on an opposite side with respect to a first surface of the at least one second substrate via a plurality of conductor bumps such that the first surface of the at least one second substrate has a component mounting region,
wherein the first substrates have substantially a same thickness and are formed such that the first conductor layers and the first insulating layers are laminated on a first surface of the first core substrate and on a second surface of the first core substrate on an opposite side with respect to the first surface of the first core substrate, and the at least one second substrate is formed such that the second conductor layers and the second insulating layers are laminated on a first surface of the second core substrate and on a second surface of the second core substrate on an opposite side with respect to the first surface of the second core substrate.

20. The method for manufacturing a wiring substrate according to claim 19, further comprising:
integrating the plurality of first substrates with a sealing resin.
